(19) United States
(12) Patent Application Publication
(10) Pub. No.: US 2020/0378806 A1
(43) Pub. Date: Dec. 3, 2020

(54) DEVICE HAVING AN ELECTRONICS UNIT AND A HOUSING

(71) Applicant: Robert Bosch GmbH, Stuttgart (DE)

(72) Inventor: Simon Breitenbach, Stuttgart (DE)

(21) Appl. No.: 16/959,762

(22) PCT Filed: Nov. 8, 2018
(86) PCT No.: PCT/EP2018/080572

§ 371 Date: Jul. 2, 2020

(30) Foreign Application Priority Data
Jan. 12, 2018 (DE) 10 2018 200 511.7

(51) Int. Cl. G01D 11/24; H05K 7/14

(52) U.S. Cl. CPC G01D 11/245; H05K 7/1427

(57) ABSTRACT

A device having an electronics unit and a housing. The housing has at least one first housing part and one second housing part, which are developed and joined in such a way that electronics unit is enclosed by the housing, the first housing part and/or the second housing part being developed as a foil.

### FIELD

The present invention is based on a device having an electronics unit and a housing.

### BACKGROUND INFORMATION

Conventionally, an electronics unit of a device may be enclosed in a housing by encapsulating the electronics unit in plastic material or extrusion-coating it with plastic material.

Such devices typically have a firm housing, which is produced from a plastic material, for instance with the aid of an injection molding process. Housings made from metal, which enclose the electronics unit appropriately, are available as well. However, these metal housings can shield wireless communications units of the electronics unit.

### SUMMARY

The present invention relates to a device having an electronics unit and a housing.

When speaking of an electronics unit, this means that the electronics unit has electronic components such as a sensor unit and/or a processing unit and/or a memory element and/or a communications unit.

According to one aspect of the present invention, the housing has at least one first housing part and one second housing part, which are developed and joined in such a way that the electronics unit is enclosed by the housing, the first housing part and/or the second housing part being developed as a foil.

Such a housing having at least one housing part developed as a foil is typically referred to as blister packaging. It offers the advantage of allowing a housing part developed as a foil to be produced in a considerably more economical manner than a housing part produced with the aid of an injection molding process, for instance. As a result, the costs of the device are able to be reduced accordingly, the costs including both the production and the material costs. Despite these low costs, the housing parts developed as a foil offer a possibility of protecting the electronics unit from undesired external influences, e.g., from contamination or moisture. This makes it possible to achieve a protection rating certification (international protection code) according to IP54 or higher.

In addition, a housing part developed as a foil has a considerably lower weight than an injection-molded part so that, for example, transport costs of the device are able to be reduced.

Foil is to be understood as an object which is developed so that its thickness is lower by multiple orders of magnitude in relation to its width and in relation to its length.

In one specific embodiment of the device according to the present invention, it is provided that the first housing part and/or the second housing part has/have at least one fastening element. This offers the advantage of allowing the device to be attached to an object with the aid of the fastening element. A corresponding object may be a transport good, for example.

According to one specific embodiment of the device according to the present invention, it is provided that the fastening element is developed as a wing-type element, which particularly projects outward from the housing. This has the advantage that it is very easy to reach the fastening element from outside the housing, and the fastening means is not shielded by other components of the device. This may make it easier to attach the device to a corresponding object. In addition, the fastening element does not affect the properties of the housing such as the stability and/or transparency.

According to one specific embodiment of the device according to the present invention, it is provided that the at least one fastening element has at least one perforation. This has the advantage that the device is able to be nailed and/or stapled and/or screwed to a corresponding object with the aid of the perforation in order to attach the device to the object.

According to one specific embodiment of the device according to the present invention, it is provided that the first housing part has a first region which is developed in such a way that the first housing part is more elastic in the first region than outside the first region. This has the advantage that the housing part initially yields in the elastic region under the action of an external force. This makes it possible to realize corresponding functions of the device, e.g., the possibility of operating a switching element of the electronics unit, which is appropriately situated inside the housing.

According to one specific embodiment of the device according to the present invention, it is provided that the first housing part at least partially has a groove in the first region. This offers the advantage that such a groove is able to affect the elasticity of the housing part accordingly. For instance, regions that are surrounded by the first region are therefore easier to move. In addition, a groove may represent an optical demarcation for a possible user so that, for instance, the user is able to understand that a possible function of the device is integrated in a region surrounded by a corresponding groove.

According to one specific embodiment of the device according to the present invention, it is provided that a thickness of the first housing part in the first region is thinner than a thickness of the first housing part outside the first region. This has the advantage that a thinner housing part has greater elasticity than a thicker housing part.

The corresponding thickness of the first housing part in the first region is given by a wall thickness of the groove, in particular, especially preferably by a wall thickness of a base of the groove.

According to one specific embodiment of the device according to the present invention it is provided that the first housing part has at least one second region, which is developed so that the stability of the first housing part inside the second region is greater than outside the second region, and in particular a third region has greater protection from mechanical effects in comparison with outside the third region. This has the advantage that the electronics unit in the interior of the housing is particularly well protected because the housing does not yield quite as easily in response to forces acting from the outside. In addition, the housing therefore includes a third region, which is particularly protected.

According to one specific embodiment of the device according to the present invention, it is provided that the second region and the third region are part of an upper side of the first housing part, the first housing part in the third region being situated at an offset in the direction of an interior of the housing in relation to the second region such that the third region is at least partly surrounded by the elevated second region.

This has the advantage that the elevated second region protects the third region from being exposed to mechanical influences and/or ensures that such mechanical influences are not readily able to reach the third region. On the one hand, the electronic components of the electronics unit situated in this region are able to be protected in this way, and on the other hand, for instance, an element may additionally also be placed on the outer side of the housing part in the third region, this element then still being able to be protected by the elevated second region. For example, such an element may have a sticker and/or a QR code, which can be used for identifying the device.

According to one specific embodiment of the device according to the present invention, it is provided that the electronics unit has at least one switching element, the switching element in particular being positioned in such a way that it is situated below the third region in its actuating direction. This has the advantage that corresponding control commands are able to be transmitted from a user to the electronics unit of the device by way of the switching element. The switching element may have a push button and/or a toggle switch, for instance. Because the third region is situated at a greater depth, it is especially also possible to reduce the clearance between the first housing part and the switching element, which also makes it easier to actuate the switching element. In addition, it is possible to reduce the risk of an unintended actuation of the switching element.

According to one specific embodiment of the device according to the present invention, it is provided that an upper side of the switching element extends in parallel with the upper side of the first housing part in the third region. This has the advantage that the switching element is able to be operated in the easiest and most reliable manner possible.

According to one specific embodiment of the device according to the present invention, it is provided that the second region of the first housing part has at least one edge, the second region in particular including a side wall of the first housing part, and the edge in particular extending in parallel with an upper edge of the side wall. This has the advantage that each additional edge increases the stability of the housing.

An edge is to be understood as a line where two surfaces meet at an angle; the angle is freely selectable but may not be 0°, 180° or a multiple of 180°.

According to one specific embodiment of the device according to the present invention, it is provided that the first housing part and/or the second housing part has/have an essentially or regionally optically transparent development. This has the advantage that optical radiation from the interior of the housing is able to reach the outside and/or is able to reach the interior of the housing [from the outside]. In this way, for instance, a potential user is able to see the interior of the housing. For example, a user is able to visually perceive information that may be emitted by a display element of the electronics unit.

In this context, ‘optical transparency’ is meant to describe that optical radiation is able to penetrate the material. The optical radiation able to penetrate the material in particular has a predefined wavelength range in this instance. However, it is also possible that radiation of any wavelength is able to penetrate the material.

According to one specific embodiment of the device according to the present invention, it is provided that the foil of the first housing part and/or the second housing part is a plastic foil which includes a biomaterial, in particular. This offers the advantage that a plastic foil will not electromagnetically shield a possible communications unit of the electronics unit. Moreover, when a biomaterial is used, the device may also be used in areas where special preconditions exist with regard to the used material. For instance, this may be the case in the food sector where the material has to be nontoxic, for example.

According to one specific embodiment of the device according to the present invention, it is provided that the first housing part and/or the second housing part has/have an adhesive material and in particular a one-sided or double-sided adhesive coating. For example, this offers the advantage that the housing parts are able to be adhesively joined to each other. In this context, such an adhesive connection is able to be realized in a very simple and economical manner. Another advantage, for instance, is that the electronics unit can be connected to one of the housing parts by the adhesive material or else the housing part is able to be mounted on an object with the aid of the adhesive material, which therefore allows for an uncomplicated yet stable affixation of the electronics unit or the device. A foil provided with an adhesive coating may be an adhesive tape, for instance.

According to one specific embodiment of the device according to the present invention, it is provided that the electronics unit is developed as a data logger. The device according to the present invention is advantageously able to be used for monitoring an object by placing the device in an object or on the object or in an environment of the object. For this purpose, an appropriately developed electronics unit in particular has a sensor unit for sensing at least one of the environment parameters acting on the object as well as a memory element for storing the at least one sensed environment parameter. Based on the sensed and stored environment parameters, it is possible to check whether the object has been properly handled during transport, for instance. Depending on the specific embodiment of the sensor unit, for example, it is possible to check whether the object was subjected to shocks or whether threshold values for moisture and/or temperature were exceeded.

The low weight of the housing compared with conventional housings offers the additional advantage that lower damping of external influences is acting on the electronics unit, with the result that the sensing of the environment parameters acting on an object is affected to a lesser degree.

### BRIEF DESCRIPTION OF THE DRAWINGS

FIG. 1 shows a perspective view of a first exemplary embodiment of a device according to the present invention.

FIG. 2 shows a first section through the first exemplary embodiment of a device according to the present invention according to FIG. 1.

FIG. 3 shows a second section through the first exemplary embodiment of a device according to the present invention according to FIG. 1.

FIG. 4 shows a section through a second exemplary embodiment of a device according to the present invention.

### DETAILED DESCRIPTION OF EXAMPLE EMBODIMENTS

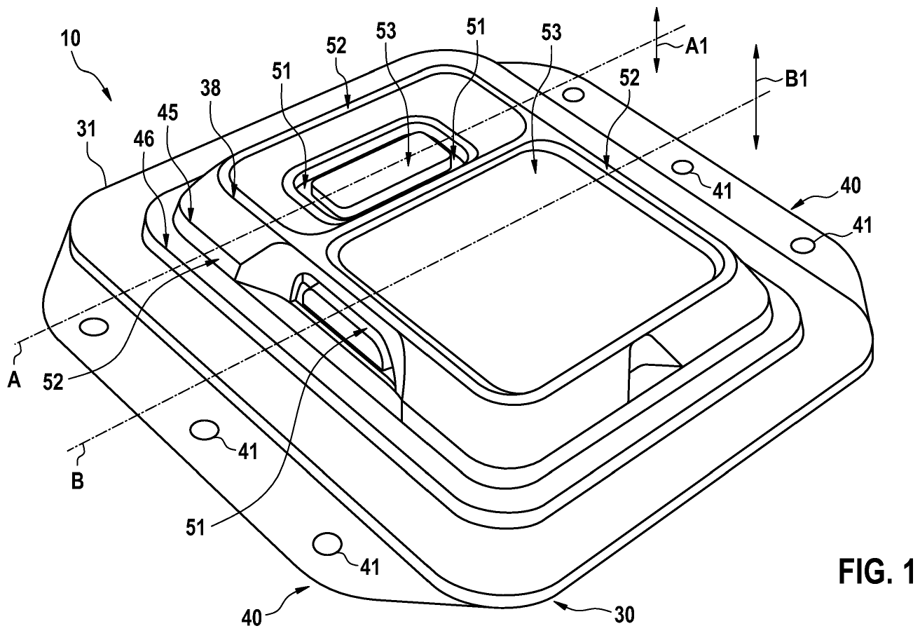

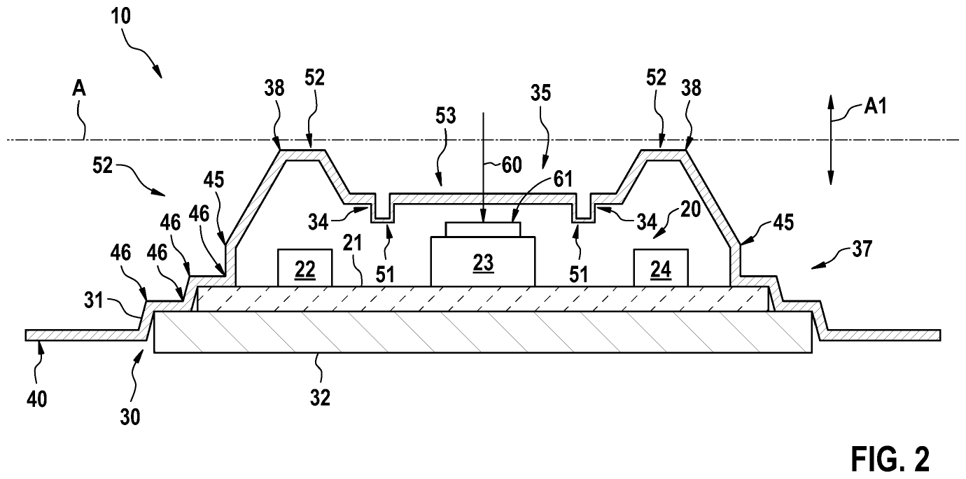

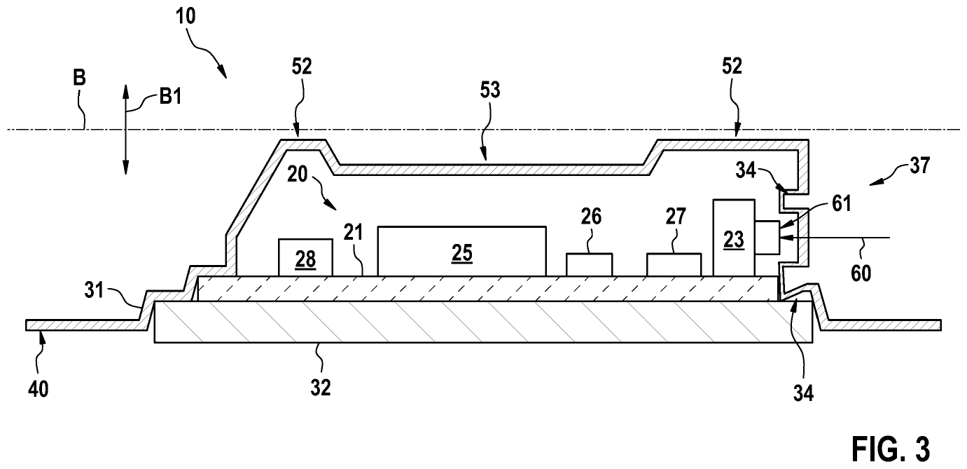

FIG. 1 shows a perspective view of a first exemplary embodiment of a device according to the present invention. Shown is a device 10, which has a housing 30. Housing 30 includes a first housing part 31 and a second housing part 32, but second housing part 32 is not visible here because it is covered by first housing part 31. First housing part 31 has two fastening elements 40. Fastening elements 40 are developed as wing-type elements in this case and project from housing 30 in the outward direction. In addition, each fastening element 40 has a plurality of perforations 41, which are embodied in the form of holes by way of example. First housing part 31 also has first regions 51, second regions 52, and third regions 53, which will be described in greater detail in FIG. 2 and FIG. 3 described below.

FIG. 2 shows a first section through the first exemplary embodiment of a device of the present invention according to FIG. 1. The sectional plane includes cutting line A shown in FIG. 1 and extends perpendicular to this cutting line A through device 10, which is symbolized by double arrow A1. In addition to housing 30, which encompasses first housing part 31 and second housing part 32, device 10 also includes an electronics unit 20.

First housing part 31 and second housing part 32 are embodied and joined in such a way that electronics unit 20 is enclosed by housing 30. In addition, first housing part 31 and second housing part 32 are developed as a foil. Housing parts 31, 32 may be produced by deep-drawing of a foil, for instance, in particular by thermoforming. For example, this foil may preferably be a plastic foil, which especially preferably has a thickness of between 0.1 mm and 5 mm. In a particularly preferred manner, the plastic foil includes a biomaterial. Alternatively, however, only one of housing parts 31, 32 may be developed as a foil.

Second housing part 32 in particular has an adhesive material which may be developed as an adhesive coating. Especially preferably, second housing part 32 has a double-sided adhesive coating and, for instance, is developed as a double-sided adhesive tape with the aid of which second housing part 32 is able to be bonded to first housing part 31, in particular.

First housing part 31 has a more elastic development in first regions 51 than outside these first regions 51. This greater elasticity in first regions 51 is achieved in that first regions 51 at least partially have a groove 34 and/or in that first housing part 31 has an at least partly thinner development in first regions 51 than first housing part 31 outside these first regions 51. In particular, first regions 51 have a groove 34 whose wall thickness is reduced in comparison with a wall thickness of first housing 31 outside first region 51. Especially preferably, the wall thickness of a base of groove 34 is reduced.

In addition, the foil of first housing part 31 and/or second housing part 32 may at least regionally have an optically transparent development. This is able to be achieved in that the foil has a thin development such that an optical transparency of the foil is achieved. Alternatively, for example, the foil may have a material composition which is permeable to optical radiation, in particular within a predefined wavelength range. As an alternative thereto, the foil may also be regionally coated so that housing part 31, 32 only has an optical transparency in the particular region for optical radiation of a predefined wavelength.

In addition, first housing part 31 also has second regions 52, which are developed in such a way that the stability of first housing part 31 inside second regions 52 is greater than outside second regions 52. Moreover, first housing part 31 in particular also has a third region 53, which has greater protection from mechanical influences than outside third region 53. Second region 52 and third region 53 may be part of an upper side 35 of first housing part 31, first housing part 31 in third region 53 being offset in the direction of an interior of housing 30i in relation to second region 52 in such a way that third region 53 is surrounded by elevated second region 52.

In addition or as an alternative, at least one of second regions 52 of first housing part 31 may have at least one edge 45, this second region 52 in particular including a side wall 37 of first housing part 31, and edge 45 in particular extending in parallel with an upper edge 38 of side wall 37. In this exemplary embodiment, this second region 52 of first housing part 31 also has further edges 46, which likewise increase the stability of housing 30 and are developed in such a way that they may additionally be used for positioning electronics unit 20 in relation to first housing part 31, for instance, or also for positioning second housing part 32 in relation to first housing part 31.

For instance, electronics unit 20 has a circuit board 21 on which corresponding electronic components are situated. These electronic components, for instance, may be a sensor unit 22 and/or a switching element 23 and/or a communications unit 24. Sensor unit 22, for instance, may include an acceleration sensor and/or a temperature sensor and/or a magnetic field sensor and/or a moisture sensor and/or a light sensor in order to sense corresponding environment parameters such as the humidity or vibrations.

Switching element 23 may be embodied as a push button, for example, and be placed in such a way that an actuation of switching element 23 from outside the housing in an operating direction 60 is possible. Toward this end, switching element 23 may be disposed in such a way that it is situated in its actuating direction 60 below third region 53, which is surrounded by corresponding elastic first regions 51 in this case. In particular, an upper side 61 of switching element 23 extends in parallel with upper side 35 of first housing part 31 in third region 53. Communications unit 24 is particularly able to be developed as a wireless communications unit, e.g., as a WLAN unit and/or a Bluetooth and/or a LoRa unit and/or as a mobile radio unit.

FIG. 3 shows a second section through the first exemplary embodiment of a device of the present invention according to FIG. 1.

The sectional plane includes cutting line B shown in FIG. 1 and extends perpendicular to this cutting line B through device 10 and is symbolized by double arrow B1. Electronics unit 20 additionally includes, for instance, an energy supply element 25 and/or a further switching element 23. For example, energy supply element 25 may include an energy store and/or an energy harvesting unit. The energy store may have a battery and/or a capacitor, for instance. Further switching element 23 is developed in such a way that its actuating direction 60 extends perpendicular to actuating direction 60 of switching element 23 described in FIG. 2. Accordingly, side wall 37 of first housing part 31 is developed in such a way that it has a further groove 34 that surrounds an area which lies in actuating direction 61 of further switching element 23 in parallel with an upper side 61 of further switching element 23. This makes it possible to actuate further switching element 23 from the side.

In addition, electronics unit 20 may include a processing unit 26 and/or a memory element 27 and/or a display element 28, for instance. Processing unit 26, for example, is able to be developed as a microcontroller and in particular may also have an already integrated memory element 27. Display element 28 may include an illumination means and/or a display, for example.

By fitting circuit board 21 with corresponding electronic components, electronics unit 20 may be developed as a data logger which is able to acquire and store environment parameters. To allow electronics unit 20 to be used as a data logger particularly requires at least sensor unit 22 and memory element 27. Device 10 may then be used for monitoring an object. This object could be a transport good, for example.

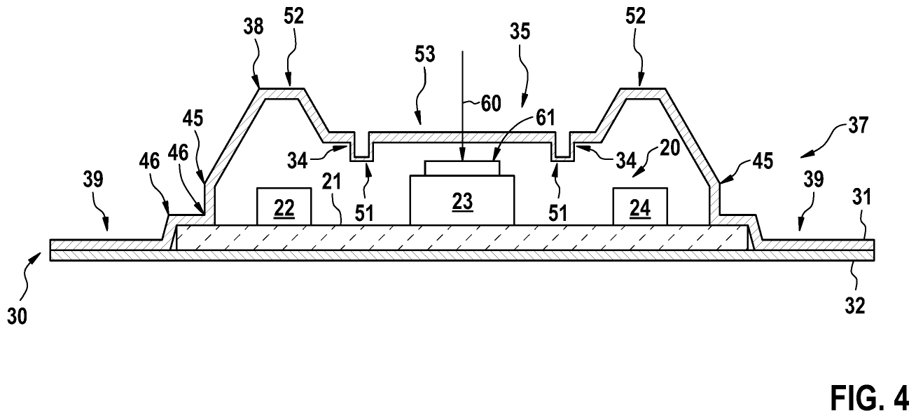

FIG. 4 shows a section through a second exemplary embodiment of a device according to the present invention. This section orients itself on the section according to FIG. 2, the devices of the two exemplary embodiments having a virtually identical development.

The second exemplary embodiment differs from the first exemplary embodiment in that second housing part 32 extends into edge regions 38 of housing 30, which also include fastening elements 40, and runs in parallel with first housing part 31 in these edge regions 38. First housing part 31, for instance, is welded to second housing part 32 in edge regions 38 of housing 30. However, it is also possible that first housing part 31 and second housing part 32 are additionally or alternatively bonded to each other in edge regions 38.

Electronics unit 20 may also be bonded to second housing part 32, for instance together with its circuit board 21. In addition or as an alternative, electronics unit 20 may also be clamped between first housing part 31 and second housing part 32, which are appropriately developed for this purpose to hold electronics unit 20 in place in housing 30.

1-13. (canceled)

14. A device, comprising:
an electronics unit; and
a housing, wherein the housing has at least one first housing part and at least one second housing part which are configured and joined in such a way that the electronic unit is enclosed by the housing, the first housing part and/or the second housing part being formed from a foil.

15. The device as recited in claim 14, wherein the at least one first housing part and/or the at least one second housing part has at least one fastening element.

16. The device as recited in claim 15, wherein the fastening element is a wing-type element, which projects outward from the housing.

17. The device as recited in claim 15, wherein the at least one fastening element has at least one perforation.

18. The device as recited in claim 14, wherein the at least one first housing part has a first region which is formed in such a way that the at least one first housing part is more elastic in the first region than outside the first region.

19. The device as recited in claim 18, wherein the at least one first housing part at least partially has a groove in the first region.

20. The device as recited in claim 18, wherein a thickness of the at least one first housing part is thinner in the first region than a thickness of the first housing part outside the first region.

21. The device as recited in claim 14, wherein the at least one first housing part has at least one second region and a third region, which is formed in such a way that a stability of the first housing part inside the second region is greater than outside the second region, and a third region has greater protection from mechanical effects than outside the third region.

22. The device as recited in claim 21, wherein the at least one second region and the third region are part of an upper side of the first housing part, the first housing part in the third region being situated at an offset in a direction of an interior of the housing in relation to the second region such that the third region is at least partly surrounded by an elevated portion of the second region.

23. The device as recited in claim 22, wherein the electronics unit has at least one switching element, the switching element being positioned in such a way that switching element is situated below the third region in an actuating direction of the switching element.

24. The device as recited in claim 23, wherein an upper side of the switching element extends in parallel with the upper side of the first housing part in the third region.

25. The device as recited in claim 21, wherein the at least one second region of the first housing part has at least one edge, the at least one second region including a side wall of the first housing part, and the edge extending in parallel with an upper edge of the side wall.

26. The device as recited in claim 14, wherein the at least one first housing part and/or the at least one second housing part is at least regionally optically transparent.
